(19) United States
(12) Patent Application Publication
(10) Pub. No.: US 2015/0236302 A1
(43) Pub. Date: Aug. 20, 2015

(54) ORGANIC LIGHT-EMITTING DISPLAY DEVICE

(71) Applicant: NEOVIEW KOLON CO., LTD., Hongseong-gun Chungcheongnam-do (KR)

(72) Inventors: Chung-Hyoun Gyoung, Gyeonggi-do (KR); Hui-Chul An, Boryeong-si (KR); Dae-Yong Kim, Seoul (KR); Woo-Bin Im, Hongseong-gun (KR)

(73) Assignee: NeoView KOLON Co., Ltd., Hongseong-gun, Chungcheongnam-do (KR)

(21) Appl. No.: 14/429,575

(22) PCT Filed: Sep. 24, 2013
(86) PCT No.: PCT/KR2013/008505

§ 371 Date: Mar. 19, 2015

(30) Foreign Application Priority Data
Sep. 24, 2012 (KR) 10-2012-0106063
Sep. 23, 2013 (KR) 10-2013-0112665

(51) Int. Cl. H01L 51/52; G02B 27/01

(52) U.S. Cl. CPC H01L 51/5271; H01L 51/5275; G02B 27/0101

(57) ABSTRACT

Disclosed is an organic light-emitting display which has an increased image formation distance, such that a position of an image formed in the organic light-emitting display used as a display unit for a head-up display is located in front from an actual position of the organic light-emitting display. An organic light-emitting display 300 of a preferred embodiment includes a front substrate 310 on which a positive electrode is formed; a rear substrate 330 on which a negative electrode is formed; an organic light-emitting layer 320 which is inserted between the front and rear substrates 310 and 330, and partitioned into a plurality of pixels; an optical unit 340 including a plurality of micro lenses 340a disposed on any one of both surfaces of the front substrate 310 or on both surface thereof, and disposed at positions corresponding to each of the plurality of pixels 320a.

### BACKGROUND OF THE INVENTION

1. Field of the Invention

The present invention relates to an organic light-emitting display, and more particularly, to an organic light-emitting display which is appropriately used for a head-up display of transportation means such as a vehicle or an aircraft, by increasing an image formation distance of an image generated in an emission region of the display and thus displaying the image with an increased image formation distance.

2. Description of the Related Art

A head-up display (HUD) refers to a display designed to display driving information of a transportation means such as a vehicle or an aircraft in front of a driver without a driver driving the transportation means being required to move their eyes. Meanwhile, in the early stage of a use of the head-up display in vehicles, the head-up display typically displayed information of an instrument panel such as a speedometer, a fuel gauge, and a temperature gauge of the vehicle. However, the head-up display having a function of displaying specific information among display screens of a navigation system by operating together with the navigation system which aids in way finding, and the like, through a map guide, has also recently emerged.

An example of the head-up display used for this purpose may include a so-called projection type head-up display which projects an image generated from an image generation apparatus to a windshield of a vehicle to display the projected image. However, since the projection type head-up display has an increased volume and cost, and the like, due to a complicated optical system, a head-up display of a type of directly integrating the head-up display using a plane type display, such as a transparent organic light-emitting display (TOLED) as a display unit, with the windshield of the vehicle, or a head-up display of a type of being installed in a vehicle inwardly of the windshield, has been developed and used.

In general, in order to confirm a road condition, a distance from a vehicle ahead, and the like, the driver's eyes during driving typically focus at a relatively distant point spaced apart from the front of the vehicle by a predetermined distance, but since the head-up display is installed in the windshield or in front of the windshield inside the vehicle, a difference of a considerable distance between the driver's focus and the head-up display occurs.

Therefore, in order for a driver driving a vehicle to confirm the driving information displayed on the head-up display, the focus of the driver moves to the head-up display in front of the windshield from a position in front of the vehicle at which the driver's eyes focus during driving. A change in a focal distance of the driver's eyes due to the movement is inevitable, but since a slight parallax is present between the movement of the eyes and the actual change in the focal distance of the eyes, when the driver's focus moves to the head-up display from the front range of vision or conversely, a period in which the driver's eyes are out of focus during the time corresponding to the parallax is present and in some cases, it may be difficult to keep the driver's focus in front of the vehicle.

In general, when the image formation position of the head-up display is positioned at the front or rear approximately 2 m from the driver's eyes, it is known that the foregoing problem does not occur.

To solve the foregoing problems, it is preferable that the image formation position at which the image, formed on the head-up display disposed in the vicinity of the windshield of the vehicle, is recognized by human eyes generally coincides with the position of the driver's focus during driving, if possible. An example of a technique of increasing the image formation distance of the head-up display, to dispose the image formation position of the head-up display outside the windshield, and not at the actual position of the head-up display, may include a technique disclosed in Korean Patent Laid-Open Publication No. 10-2012-59846.

For reference, in the present specification, the term ‘image formation distance’ refers to a distance between a position at which an image, formed by light emitted from an organic light-emitting layer of the organic light-emitting display, used as a display unit of the head-up display, is visually recognized by the driver and the driver's eyes. In the present invention, the image formation distance is longer than the distance from the driver's eyes to the installation position of the organic light-emitting display, such that the driver may recognize that the image is formed in front of the head-up display

FIG. 1 is a cross-sectional view schematically illustrating a configuration of a head-up display according to the related art which is disclosed in Korean Patent Laid-Open Publication No. 10-2012-59846.

According to the conventional head-up display disclosed in the above Patent Publication, an OLED 100, which separates and sends out a left eye image and a right eye image, is inserted into inner and outer adhesive films 230 and 240 which are respectively adhered to double glass panes 210 and 220 of the windshield for a vehicle, and is heated and pressed to adhere thereto, and a lenticular sheet 110, on which semi-cylindrical lenticular lenses are concentrated is adhered thereon, such that the OLED 100 separates the left and right images depending on an angle of each lens of the lenticular sheet 110 so as to generate a binocular parallax to show the image as a three-dimensional image, thereby increasing the image formation distance by a method for allowing a three-dimensional image to appear as an image formed at a remote distance.

### SUMMARY OF THE INVENTION

The technique disclosed in the above Patent Publication adopts a three-dimensional method for three-dimensionally displaying the display image, due to the generation of the binocular parallax, as the method for increasing the image formation distance of the head-up display, and adopts an OLED which separates and sends out the left eye image and the right eye image as the display for executing the same.

However, as disclosed in the above Patent Publication, the increase in the image formation distance, due to the three-dimensional image, may be possible. However, since the three-dimensional image is not an actual three-dimensional image but is an image which is three-dimensionally formed by artificially generating the binocular parallax, there is a problem in that the driver may feel a sense of fatigue when he/she alternately shifts focus between the front of the vehicle and the image on the head-up display.

Further, although not specifically disclosed in the above Patent Publication, the OLED requires a complicated optical configuration for separating the left eye image and the right eye image, so as to separate and send out the left eye image and the right eye image, which may lead to the increase in the volume and cost of the head-up display.

Further, in the above Patent Publication, the separate lenticular sheet is attached to the outside of the OLED in order to increase the image formation distance of the OLED, and therefore the structure may also be complicated.

In consideration of the above-mentioned circumstances, it is an object of the present invention to provide an organic light-emitting display, which does not need an additional component other than an OLED as disclosed in the above Patent Document, and may increase an image formation distance of a display image, without three-dimensionally implementing an image, by artificially generating a binocular parallax while increasing the image formation distance of an image displayed by the OLED.

In order to accomplish the foregoing object, according to an embodiment of the present invention, there is provided an organic light-emitting display including an organic light-emitting layer inserted between a first electrode and a second electrode which are each formed between a first substrate and a second substrate, the organic light-emitting display including: an optical unit which is disposed on any one of both surfaces of the first substrate or on both surface thereof to increase an image formation distance of an image formed by light emitted from the organic light-emitting layer.

According to another embodiment of the present invention, there is provided an organic light-emitting display including an organic light-emitting layer inserted between a first electrode and a second electrode which are each formed between a first substrate and a second substrate, the organic light-emitting display including: a first optical unit disposed on any one of both surfaces of the first substrate; and a second optical unit disposed on a surface of the second substrate facing the organic light-emitting layer, wherein the first optical unit and the second optical unit are configured to increase an image formation distance of an image formed by light emitted from the organic light-emitting layer.

As described above, since the organic light-emitting display of the present invention may increase the image formation distance of the display image by the simple configuration thereof, when the organic light-emitting display is used as the head-up display of the transportation means such as a vehicle, the organic light-emitting display does not need an additional component, other than the organic light-emitting display, and may increase the image formation distance of the display image without three-dimensionally implementing the image, by artificially generating the binocular parallax, while increasing the image formation distance of the display image by use of only the organic light-emitting display.

### BRIEF DESCRIPTION OF THE DRAWINGS

FIG. 1 is a cross-sectional view schematically illustrating a configuration of a head-up display of the related art.

FIG. 2 is a cross-sectional view schematically illustrating a configuration of an OLED according to preferred Embodiment 1 of the present invention.

FIG. 3 is a diagram schematically illustrating an appearance in which an erected (upright) virtual image, with an image formation distance of an image increased by the OLED according to preferred Embodiment 1 of the present invention, is formed.

FIG. 4 is a cross-sectional view schematically illustrating a configuration of an OLED 301 according to Modified Example 1.

FIG. 5 is a cross-sectional view schematically illustrating a configuration of an OLED 303 according to Modified Example 2.

FIG. 6 is a cross-sectional view schematically illustrating a configuration of an OLED 305 according to Modified Example 3.

FIG. 7 is a cross-sectional view schematically illustrating a configuration of an OLED 400 according to Embodiment 2 of the present invention.

FIG. 8 is a diagram schematically illustrating an appearance in which an erected virtual image, with an image formation distance increased by the OLED 400 according to Embodiment 2 of the present invention, is formed.

FIG. 9 is a cross-sectional view schematically illustrating a configuration of an OLED 401 according to Modified Example 4.

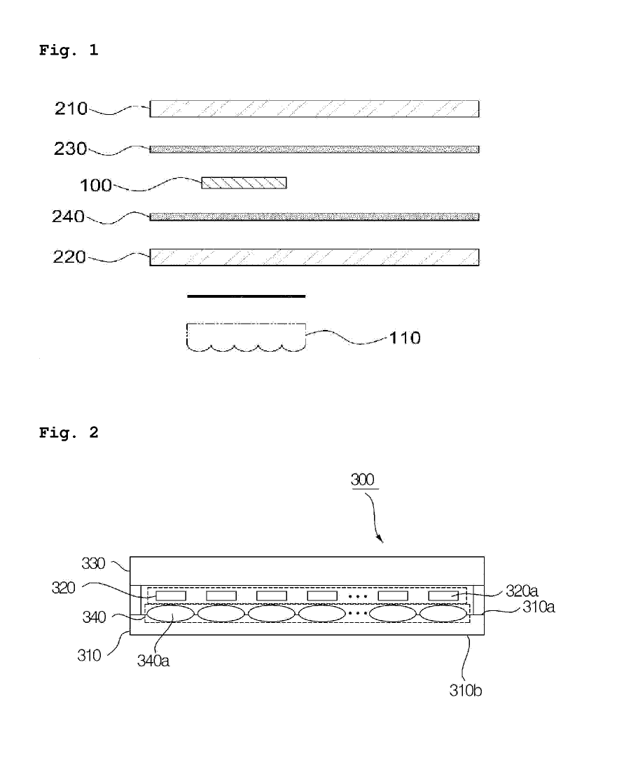

### DETAILED DESCRIPTION OF THE INVENTION

Hereinafter, preferred embodiments of the present invention will be described in detail with reference to the accompanying drawings.

### 1. Embodiment 1

First, an organic light-emitting display (hereinafter simply referred to as an ‘OLED’) 300 according to preferred Embodiment 1 of the present invention will be described. FIG. 2 is a cross-sectional view schematically illustrating a configuration of an OLED 300 according to preferred Embodiment 1 of the present invention.

As illustrated in FIG. 2, the OLED 300 according to Embodiment 1 includes an organic light-emitting layer 320 inserted between a front substrate 310 and a rear substrate 330, and an optical unit 340 disposed on a surface 311a of the front substrate 310 facing the organic light-emitting layer 320.

Further, although not illustrated in FIG. 2, the OLED 300 includes: a positive electrode which is formed on the front substrate 310; and a negative electrode which is formed between the rear substrate 330 and the organic light-emitting layer 320, or on the rear substrate 330. In the OLED 300, when holes and electrons are recombined, by injecting the holes and electrons into the organic light-emitting layer 320 from a pair of electrodes, configured as a positive electrode and the negative electrode, excitons are generated, and thereby the OLED 300 emits light due to the emission of light which occurs as the activation of the excitons is lost.

A transparent substrate made of a transparent material such as glass or plastic may be used as the front substrate 310. In addition, the positive electrode may include an electrode (not illustrated) formed on the front substrate 310 at positions corresponding to each of a plurality of pixels 320a of the organic light-emitting layer 320 to be described below by a known method. The electrode may be coated with a conductive material or made of a material such as ITO and IZO, for instance.

The organic light-emitting layer 320 is a layer made of an organic light-emitting material from which light is emitted in response to an electric field applied between the positive electrode and the negative electrode. As illustrated in FIG. 2, the organic light-emitting layer 320 is partitioned into the plurality of pixels 320a in which regions corresponding to the plurality of positive electrodes and negative electrodes (not illustrated) are an emission region.

The negative electrode is disposed on the organic light-emitting layer 320 and the rear substrate 330 is disposed on the negative electrode. However, the negative electrode may be directly formed on the rear substrate 330.

A transparent substrate made of glass, plastic, or the like may be used as the rear substrate 330. In this regard, the rear substrate 330 serves as a cover substrate for the OLED 300.

The optical unit 340 is disposed at positions corresponding to the plurality of pixels 320a to serve to increase the image formation distance of the image generated by the emission of the plurality of pixels 320a. According to the present embodiment, the optical unit 340 includes a plurality of micro lenses 340a which are disposed at positions corresponding to each of the plurality of pixels 320a.

According to the present embodiment, the micro lens 340a is disposed on a first surface 310a of the front substrate 310 which is a surface facing the organic light-emitting layer 320.

Further, according to the present embodiment, each of the plurality of pixels 320a of the organic light-emitting layer 320 is arranged in a first periodic arrangement interval from the adjacent pixels 320a. Herein, the term ‘periodic arrangement interval’ means that: an interval from a center of any one pixel to a center of a pixel adjacent thereto; or an interval from one end of any one pixel to one end of a pixel adjacent thereto, is arranged at the same interval over all of the plurality of pixels, and is the same concept as ‘pitch’ generally used in the technical field to which the present invention pertains.

Further, each of the plurality of micro lenses 340a has a second periodic arrangement interval from the adjacent micro lenses 340a, and the first periodic arrangement interval and the second periodic arrangement interval may be the same as each other, or may not be the same as each other, but it is more preferable that the first and second period arrangement intervals be the same as each other.

Meanwhile, it is preferable that a size of each of the plurality of micro lenses 340a is larger than that of the emission region of the corresponding pixel 320a. That is, it is preferable that the size of each of the plurality of micro lenses 340a is larger than that of the emission region of the corresponding pixel 320a, or the size of each of the plurality of micro lenses 340a is larger than an area of the emission region of the corresponding pixel 320a. Further, it is preferable that, the distance from a central point of the micro lens 340a to the outermost portion thereof, is larger than, the distance from a central point of the emission region of the corresponding pixel 320a to the outermost portion thereof.

According to experiments of the present inventors, it is preferable that, the distance from the central point of the micro lens 340a to the outermost portion thereof, is two times smaller than, the distance from the central point of the emission region of the corresponding pixel 320a to the outermost portion thereof.

FIG. 2 illustrates that each of the plurality of micro lenses 340a is formed as convex lenses, but it is by way of example only. If a lens satisfies the above condition, the plurality of micro lenses 340a are not limited to convex lenses, but may be formed as concave lenses, plane convex lenses, plane concave lenses, or combinations thereof.

Aperture ratios of the plurality of micro lenses 340a are represented by a value (Equation 1) obtained by dividing the area of the micro lens by a square of the first periodic arrangement interval. When the aperture ratio becomes too small, light transmittance is reduced, such that luminance of the OLED 300 may be reduced. On the other hand, when the aperture ratio becomes too large, the size of the micro lens 340a of the optical unit 340 is relatively reduced, such that the increase in the image formation distance, which is the object of the present invention, may not be easily achieved, and the resolution of the image is reduced, thereby causing blurring of the image and in severe cases, not displaying the overall image but displaying only a portion of the image, and the like.

According to experiments of the present inventors, the aperture ratio of the plurality of micro lenses 340a may be less than 70%, preferably, less than 60%, and more preferably less than 50%, and therefore, may be, for example, 15%, 10%, or 5%.

$$Aperture ratio = \frac{Area of micro lens}{{( First periodic arrangement interval )}^{2}} \qquad [ Equation 1 ]$$

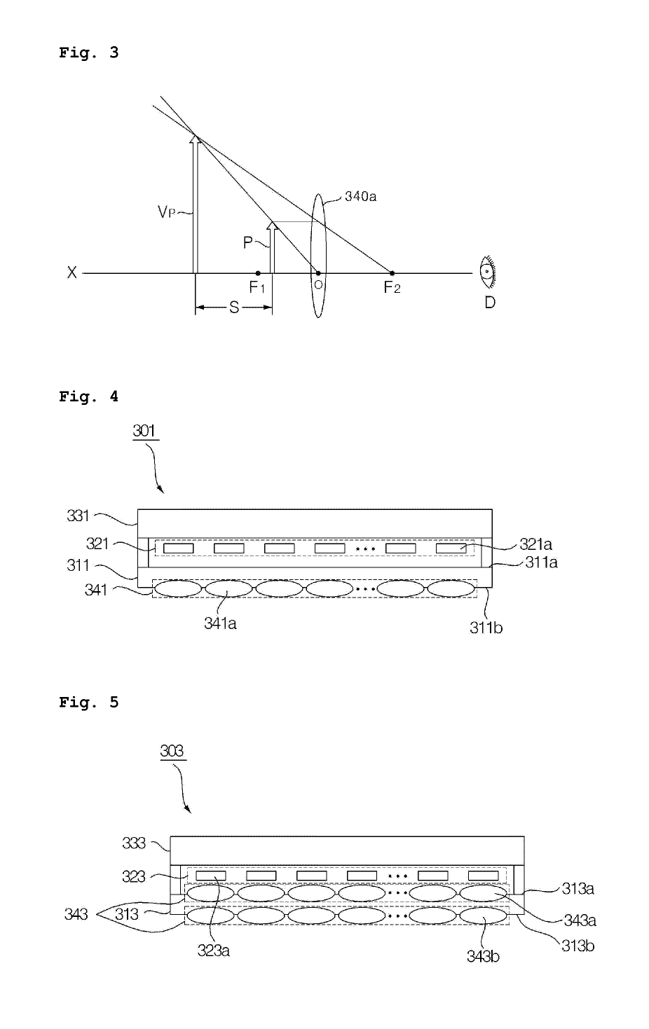

Next, an operation of the OLED 300 according to Embodiment 1 will be briefly described with reference to FIG. 3. FIG. 3 is a diagram schematically illustrating an appearance in which an erected virtual image, with the image formation distance increased by the OLED 300 according to Embodiment 1 of the present invention, is formed.

For simplification of explanation, FIG. 3 illustrates that the plurality of micro lenses 340a of the optical unit 340 are a single lens formed as convex lenses, but a person having ordinary skill in the art to which the present invention pertains will understand that it is possible to form an image when the micro lenses 340a are formed as convex lenses, concave lenses, plane concave lenses, plane convex lenses, or composite lenses configured of a combination thereof.

As is well known in the art, first, the convex lens forms a reversed real image at a back of a lens when an object is positioned outside a focus in front of the lens, and then forms an erected virtual image in front of the lens when an object is positioned inside a focus in front of the lens.

In FIG. 3, an object P corresponding to the pixel 320a of the OLED 300 is positioned within a focus F1 in front of the micro lens 340a. Therefore, based on a property of the convex lens, which refracts an incident beam, from the object P, in parallel with an axis of the micro lens 340a, and then passes the refracted ray through a focus F2, while advances a beam passing through a center O of the lens, an observer D recognizes the object P (actually, an image formed by each of the plurality of pixels 320a) as an upright virtual image at a position spaced apart from the actual position of the pixel by a distance S.

From the above description, as a method for increasing the image formation distance, by moving the image formation position of the image displayed by the organic light-emitting layer 320, the following method may be considered.

First, in FIG. 3, the erected virtual image, spaced apart from the pixel 320a by the distance S in front of the pixel 320a, is seen by the observer D (for example, a driver or the like) by adjusting the distance between the micro lens 340a of the optical unit 340 and the pixel 320a of the organic light-emitting layer 320 corresponding thereto, such that the image formation distance of the OLED 300 may be increased by adjusting the distance between the optical unit 340 and the organic light-emitting layer 320.

Alternatively, the image formation distance of the image may also be increased by further forming a buffer layer (not illustrated), made of a predetermined buffer material, between the micro lens 340a of the optical unit 340 and the pixel 320a of the organic light-emitting layer 320 corresponding thereto.

The buffer material may include any one of a photoresist material and an oxide-based compound. The photoresist material may include a positive type or a negative type and any of known photoresist materials may be used. The oxide-based compound may include SiO₂, TiO₂, Al₂O₃, Ta₂O₅, HfOx, and the like.

Further, the image formation distance of the display image may also be increased by adjusting: a focal distance of the micro lens; a material of the micro lens (for example, a lens material, such as glass, plastic, and photoresist); or a refractive index of the micro lens.

As described above, according to the present embodiment, the micro lenses 340a of the optical unit 340 may include at least any one of concave lenses, convex lenses, plane convex lenses, plane concave lenses, and combinations thereof. Further, if necessary, even in a single OLED 300, each of the plurality of micro lenses 340a may use different kinds of lenses or combinations thereof.

### 2. Modified Example

Next, modified examples of Embodiment 1 will be described with reference to the drawings.

### 2.1. Modified Example 1

First, Modified Example 1 will be described with reference to FIG. 4. FIG. 4 is a cross-sectional view schematically illustrating a configuration of an OLED 301 according to Modified Example 1.

The OLED 301 according to Modified Example 1 differs from the OLED 300 of Embodiment 1 in terms of the formation position of the optical unit 341, however, other components thereof are the same as Embodiment 1, and therefore a description of the same components will be omitted.

According to Embodiment 1, the optical unit 340 is disposed on the surface 310a of the front substrate 310 facing the organic light-emitting layer 320, however, as illustrated in FIG. 4, in the OLED 301 of Modified Embodiment 1, the optical unit 341 is disposed on an outer surface 311b of a front substrate 311 rather than an inner surface 311a thereof.

In detail, according to Embodiment 1, the plurality of micro lenses 340a of the optical unit 340 are each disposed at positions corresponding to each of the plurality of pixels 320a of the organic light-emitting layer 320, on the surface 311a of the front substrate 310 facing the organic light emitting layer 320, however, the plurality of micro lenses 340a of the optical unit 341 of the OLED 301, according to Modified Example 1, are disposed at positions corresponding to each of the plurality of pixels 321a of the organic light-emitting layer 321 on the outer surface 311b of the front substrate 311 rather than an inner surface 311a thereof.

As described above, since Modified Example 1 differs from Embodiment 1 in the position of the optical unit 341, the distance between the plurality of pixels 321a and the plurality of micro lenses 341a may be longer than that of Embodiment 1, such that the image formation position of the image, at which the display image of the OLED 301 is recognized by the observer D, may differ from Embodiment 1.

### 2.2. Modified Example 2

Next, Modified Example 2 will be described with reference to FIG. 5. FIG. 5 is a cross-sectional view schematically illustrating a configuration of an OLED 303 according to Modified Example 2.

The OLED 303 according to Modified Example 2 differs from the Embodiment 1 in terms of the formation position of an optical unit 343. However, other components thereof are the same as the Embodiment 1 except for the formation position of the optical unit 343. Therefore, a description of the same components will be omitted.

According to Embodiment 1, the optical unit 340 is disposed only on the surface 310a of the front substrate 310 facing the organic light-emitting layer 320, however as illustrated in FIG. 5, the optical unit 343 of the OLED 303 according to Modified Example 2 is disposed on both surfaces 313a and 313b of a front substrate 313.

In detail, according to Embodiment 1, the plurality of micro lenses 340a of the optical unit 340 are disposed at positions corresponding to each of the plurality of pixels 320a of the organic light-emitting layer 320, on the surface 311a of the front substrate 310 facing the organic light-emitting layer 320, however in the Modified Example 2, the optical unit 343 of the OLED 303 includes micro lenses of two columns having a plurality of first micro lenses 343a disposed on the surfaces 313a of the front substrate 313 at positions facing the plurality of pixels 323a of the organic light emitting layer 323 and a plurality of second micro lenses 343b disposed on the outer side 313b of the front substrate 313.

As described above, the Modified Example 2 differs from the Embodiment 1 in terms of the formation position and arrangement of the micro lens of the optical unit 343, such that the image formation position of the image at which the display image of the OLED 303 is recognized to the observer D may differ from the Embodiment 1.

### 2.3. Modified Example 3

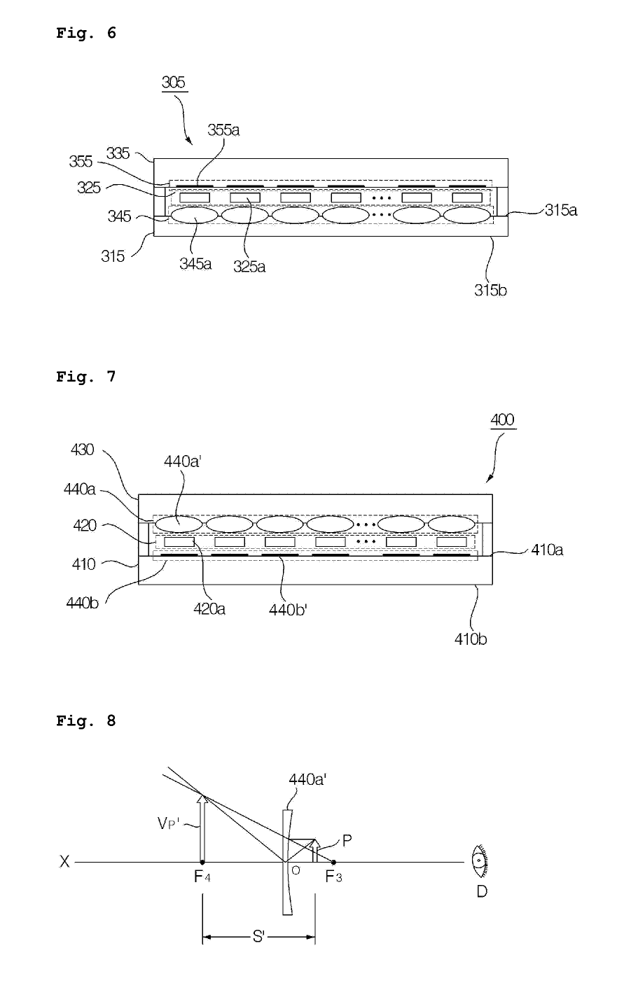

Next, Modified Example 3 will be described with reference to FIG. 6. FIG. 6 is a cross-sectional view schematically illustrating a configuration of an OLED 305 according to Modified Example 3.

A difference between Modified Example 3 and Embodiment 1 is that the OLED 300 according to Embodiment 1 includes the optical unit 340 including the micro lenses 340a disposed on the surface 310a of the front substrate 310 facing the organic light-emitting layer 320, however the OLED 305 according to Modified Example 3 includes a first optical unit 345 including the micro lenses 345a disposed on a rear surface 315a of a front substrate 315 facing the organic light-emitting layer 325 and a second optical unit 355 including a reflector 355a disposed on a front surface of a rear substrate 335 facing the organic light-emitting layer 325.

Therefore, components different from the Embodiment 1 will be mainly described and a description of the same components will be omitted.

The first optical unit 345 including the micro lenses 345a disposed on the rear surface 315a of the front substrate 315 facing the organic light-emitting layer 325 is the same as the optical unit 340 including the micro lenses 340a according to Embodiment 1.

The second optical unit 355 includes the reflector 355a disposed on the surface of the rear substrate 335 facing the organic light-emitting layer 325, and a plurality of reflectors 355a are disposed at positions corresponding to each of the plurality of pixels 325a of the organic light-emitting layer 325, on the surface of the rear substrate 335 facing the organic light-emitting layer 325.

The reflector 355a has a function of preventing the image from being distorted by passing an incident light to the OLED 305 through the rear substrate 335 from the outside through the micro lens 345a of the first optical unit 345 and a function of reflecting a light propagated to the rear surface 335 side from the plurality of pixels 325a of the organic light-emitting layer 325 to the micro lens 345a side of the first optical unit 345 to improve luminance.

Meanwhile, in FIG. 6, the second optical unit 355 including the plurality of reflectors 355a is added to the OLED 300 according to Embodiment 1, but Modified Example 3 may also be applied to the OLEDs 301 and 303 according to Modified Examples 1 and 2 by the same method.

### 3. Embodiment 2

Next, a preferred Embodiment 2 of the present invention will be described with reference to FIGS. 7 and 8. FIG. 7 is a cross-sectional view schematically illustrating a configuration of an OLED 400 according to preferred Embodiment 2 of the present invention.

A difference between Embodiment 2 and Embodiment 1 is that the OLED 300 according to Embodiment 1 includes the optical units 340 including the plurality of micro lenses 340a disposed on the surfaces of the front substrate 310 facing each of the plurality of pixels 320a of the organic light-emitting layer 320. On the other hand, an OLED 400 according to Embodiment 2 includes a third optical unit 440a including a plurality of micro mirrors 440a′ disposed on surfaces of a back panel 430 facing each of the plurality of pixels 420a of an organic light-emitting layer 420 and a fourth optical unit 440b including a plurality of reflectors 440b′ disposed on surfaces of a front panel 410 facing each of the plurality of pixels 420a of the organic light layer 420.

Therefore, the difference from Embodiment 1 will be mainly described in the present embodiment, while a description for the same components will be omitted.

The micro mirrors 440a′ included in the third optical unit 440a are any one of convex mirrors or concave mirrors.

Further, the reflector 440b′ may be made of any material if it can reflect light. The reflector 440b′ has a function of reflecting light passing through the front panel 410 from the plurality of pixels 420a of the organic light-emitting layer 420 to prevent light from coming into the observer's eyes.

Even in the present embodiment, each of the plurality of pixels 420a is arranged in a third periodic arrangement interval from the adjacent pixels, each of the plurality of reflectors 440b′ is arranged in a fourth periodic arrangement interval from the adjacent reflectors, and each of the plurality of micro mirrors 440a′ is arranged in a fifth periodic arrangement interval from the adjacent micro mirrors. The third, fourth, and fifth periodic arrangement intervals may be the same as each other, or may not be the same as each other, but it is preferable that the third, fourth, and fifth period arrangement intervals are the same as each other.

Further, the size of each of the plurality of reflectors 440b′ is larger than that of the emission region of the corresponding pixel 420a. That is, it is preferable that the size of each of the plurality of reflectors 440b′ is larger than that of the emission region of the corresponding pixel 420a or be larger than the area of the emission region of each of the plurality of pixels 420a. Further, it is preferable that the distance from a central point of the plurality of reflectors 440b′ to the outermost portion is larger than the distance from a central point of the emission region of the corresponding pixel 420a to the outermost portion.

According to experiments of the present inventors, it is preferable that the distance from the central points of each of the plurality of reflectors 440b′ to the outermost portion thereof is two times smaller than the distance from the central point of the emission region of the corresponding pixel 420a to the outermost portion thereof.

The aperture ratio of the plurality of reflectors 440b′ and micro mirror 440a′ each becomes a value (Equation 2) obtained by dividing the area of each of the reflectors or micro mirrors by a square of the third periodic arrangement interval, and for the same reason as Embodiment 1, the value may be less than 70%, preferably 60%, and more preferably 50%, and therefore may be, for example, 15%, 10%, or 5%.

$$Aperture ratio = \frac{Area of reflector}{{( Third periodic arrangement interval )}^{2}} \\ Aperture ratio = \frac{Area of micro lens}{{( Third periodic arrangement interval )}^{2}} \qquad [ Equation 2 ]$$

A principle of increasing the image formation distance of the image formed in the OLED 400 by the above configuration is illustrated in FIG. 8 by way of example, but the present embodiment differs from Embodiment 1 in terms of the position of the third optical unit 440a and a kind of optical components configuring the optical unit, and other components are substantially the same. Therefore, the image formation distance may be increased by the same method as the Embodiment 1 and a detailed description thereof will be omitted herein (see the description for the Embodiment 1).

### 4. Modified Example 4

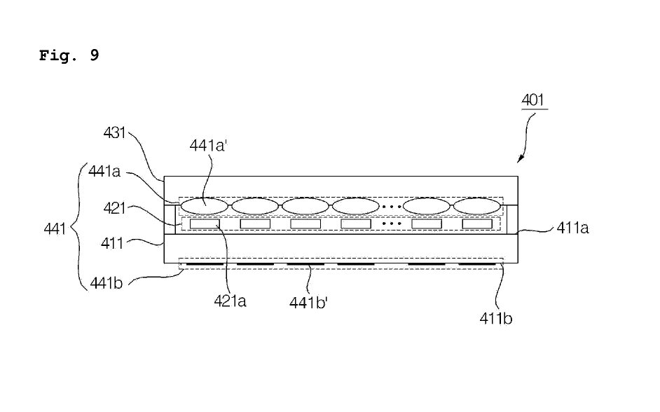

Next, Modified Example 4 will be described with reference to FIG. 9. FIG. 9 is a cross-sectional view schematically illustrating a configuration of an OLED 401 according to Modified Example 4

The OLED 401 according to Modified Example 4 is the same as Embodiment 2 in terms of the OLED 400 according to Embodiment 2 except for the position of a reflector 441b′ of a fourth optical unit 441b, while other components are the same as the Embodiment 2.

In detail, the OLED 401 according to Modified Example 4 is different from Embodiment 2 in that the fourth optical unit 441b including the plurality of reflectors 441′ is disposed at the outer surface of a front substrate 411.

In the above description, the transparent organic light-emitting display in which both of the front substrate and the rear substrate of the organic light-emitting display are used is described by way of example, but the present invention is not limited thereto and may also be applied to a front emission type organic light-emitting display or a rear emission type organic light-emitting display.

Further, each Embodiment and each Modified Example may be separately practiced and combinations thereof also may be practiced.

While the present invention has been described with reference to the preferred embodiments, it will be understood by those skilled in the related art that various modifications and variations may be made therein without departing from the scope of the present invention as defined by the appended claims.

### DESCRIPTION OF REFERENCE NUMERALS

300, 301, 303, 305, 400, 401: organic light-emitting display
310, 311, 313, 315, 410, 411: front substrate
330, 331, 333, 353, 430, 431: rear substrate
320, 321, 323, 325, 420, 421: organic light-emitting layer
320a, 321a, 323a, 325a, 420a, 421a: pixel
340, 341, 343: optical unit
355a, 440b′, 441b′: reflector

1. An organic light-emitting display including an organic light-emitting layer inserted between a first electrode and a second electrode which are each formed between a first substrate and a second substrate, the organic light-emitting display comprising:
an optical unit which is disposed on any one of both surfaces of the first substrate or on both surface thereof to increase an image formation distance of an image formed by light emitted from the organic light-emitting layer.

2. The organic light-emitting display of claim 1, wherein the organic light-emitting layer is partitioned into a plurality of pixels, and
the optical unit includes micro lenses which are disposed at positions corresponding to each of the plurality of pixels.

3. The organic light-emitting display of claim 2, wherein the micro lenses are configured as any one of convex lenses, concave lenses, plane convex lenses, plane concave lenses, and combinations thereof.

4. The organic light-emitting display of claim 2, further comprising: a buffer layer made of a buffer material between the plurality of micro lenses and the pixels.

5. The organic light-emitting display of claim 4, wherein the buffer material is any one of a photoresist material and an oxide-based compound.

6. The organic light-emitting display of claim 1, further comprising: a reflector which is disposed on a surface facing the organic light-emitting layer of the second substrate to block an incident light through the second substrate and reflect a light generated from the organic light-emitting layer and propagated to the second substrate side to the optical unit side.

7. An organic light-emitting display including an organic light-emitting layer inserted between a first electrode and a second electrode which are each formed between a first substrate and a second substrate, the organic light-emitting display comprising:
a first optical unit disposed on any one of both surfaces of the first substrate; and
a second optical unit disposed on a surface of the second substrate facing the organic light-emitting layer,
wherein the first optical unit and the second optical unit are configured to increase an image formation distance of an image formed by light emitted from the organic light-emitting layer.

8. The organic light-emitting display of claim 7, wherein the organic light-emitting layer is partitioned into a plurality of pixels,
the first optical unit includes a plurality of micro mirrors formed at positions corresponding to each of the plurality of pixels, and
the second optical unit includes reflectors formed at positions corresponding to each of the plurality of pixels.

9. The organic light-emitting display of claim 8, wherein the plurality of micro mirrors are any one of convex mirrors and concave mirrors.

10. The organic light-emitting display of claim 2, wherein aperture ratios of the micro lens, the reflector, and the micro mirror each are from 5% to 70%.

11. The organic light-emitting display of claim 2, wherein the organic light-emitting display is a transparent organic light-emitting display.
